(19) United States
(12) Patent Application Publication
(10) Pub. No.: US 2016/0013343 A1
(43) Pub. Date: Jan. 14, 2016

(54) INTEGRATED PHOTOVOLTAIC AND THERMAL MODULE (PVT)

(71) Applicant: RUTGERS, THE STATE UNIVERSITY OF NEW JERSEY, New Brunswick, NJ (US)

(72) Inventors: Dunbar Paul Birnie, III, Princeton, NJ (US); Vishnuvardhanan Vijayakumar, Tualatin, OR (US)

(21) Appl. No.: 14/771,157

(22) PCT Filed: Feb. 27, 2014
(86) PCT No.: PCT/IB14/59258

§ 371 Date: Aug. 27, 2015

Related U.S. Application Data
(60) Provisional application No. 61/770,929, filed on Feb. 28, 2013.

(51) Int. Cl. H01L 31/048; H01L 35/02; H01L 35/34; H01L 35/28

(52) U.S. Cl. CPC H01L 31/0488; H01L 35/28; H01L 35/02; H01L 35/34

(57) ABSTRACT

An integrated photovoltaic and thermal (PVT) module includes a layer of solar cells, a transparent layer, a first encapsulation layer, a second encapsulation layer, a thermally conductive and electrically insulating layer, and a thermal collector. The transparent layer is placed above the layer of solar cells. The first encapsulation layer is encapsulated in between the transparent layer and the layer of solar cells. The second encapsulation layer is encapsulated below the layer of solar cells. The second encapsulation layer conducts heat energy from the layer of solar cells. The thermally conductive and electrically insulating layer is adapted to provide electrical insulation and thermal heat transfer. The thermal collector, in contact with the thermally conductive and electrically insulating layer, is adapted to contain a heat transfer fluid. The thermally conductive and electrically insulating layer is placed in between the second encapsulation layer and the thermal collector.

### BACKGROUND

1. Technical Field

The embodiments herein generally relate to a photovoltaic and thermal (PVT) module, and, more particularly, to a design of an integrated photovoltaic and thermal module that is adhered or fastened with an adjacent silicone or polyolefin based encapsulation layer and a thermally conductive and electrically insulating layer to conduct excess heat into a thermal collector.

2. Description of the Related Art

A photovoltaic (PV) solar module typically includes a plurality of photovoltaic cells for converting solar radiation energy that enters the photovoltaic cells into electrical energy. Typical photovoltaic solar modules absorb about 70%˜90% of incident light energy, but conversion efficiency of the light energy into electricity is only about 10% to 25% depending on the type of solar cells used. The electrical performance decreases as the temperature of the photovoltaic cells increases, resulting in a reduction of the electrical power supplied by the module. Under intense sunlight in summer and in the absence of wind, the temperature of a PV solar module could be very high in relation to its reference operating temperature (e.g., 25° C.), and even over 100° C. The photovoltaic solar module's efficiency reduces by 0.42% with every degree rise in the temperature of the PV panel due to a reduction in the electronic band gap of the semiconductor used in the PV panel.

Existing PVT panels includes an EVA (Ethylene Vinyl Acetate), or a PVB (Poly-vinyl Butyral) based encapsulation layer. Both EVA and PVB have low thermal conductivity, which leads to a lower heat flow to the thermal collector, and hence a lower thermal efficiency. But, because of the higher temperatures associated with the PVT modules compared to normal PV modules (due to back thermal insulation), existing PVT modules have low reliability due to high temperature degradation of EVA and PVB encapsulation materials. Accordingly, there remains a need for a PVT module that has higher temperature stability with increased thermal conductivity transfer between a PV layer, and a heat-transfer medium.

### SUMMARY

In view of the foregoing, an embodiment herein provides an integrated photovoltaic and thermal (PVT) module. The integrated photovoltaic and thermal (PVT) module includes a layer of solar cells, a transparent layer, a first encapsulation layer, a second encapsulation layer, a thermally conductive and electrically insulating layer, and a thermal collector. The layer of solar cells includes an upper face that is exposed to solar radiation, and a lower face. The transparent layer is placed above the layer of solar cells. The transparent layer reduces a heat loss from the upper face of the layer of solar cells. The first encapsulation layer is encapsulated in between the transparent layer and the layer of solar cells. The first encapsulation layer conducts light energy from the solar radiation and transmits the light energy to the layer of solar cells. The second encapsulation layer is encapsulated below the layer of solar cells. The second encapsulation layer conducts heat energy from the layer of solar cells. The second encapsulation layer is selected from at least one of (a) a silicone, (b) a polyolefin, (c) a thermally conductive silicone, and (d) a thermally conductive polyolefin. The thermally conductive and electrically insulating layer is adapted to provide electrical insulation and thermal heat transfer. The thermal collector, in contact with the thermally conductive and electrically insulating layer, is adapted to contain a heat transfer fluid. The thermally conductive and electrically insulating layer is placed in between the second encapsulation layer and the thermal collector.

The integrated photovoltaic and thermal (PVT) module may further include (a) thermally insulated layer that is placed below the thermal collector, and (b) a back casing that is placed below the thermally insulated layer. The thermally insulated layer prevents a loss of heat energy from the thermally conductive and electrically insulating layer. The back casing provides support to the integrated PVT module. The second encapsulation may further include at least one thermally conductive filler to increase thermal conductivity of the second encapsulation layer. The at least one thermally conductive filler may be selected from at least one of (a) a ceramic nano sized particle, and (b) a ceramic micron sized particle. The at least one thermally conductive filler may be selected from a group that includes (a) a magnesium oxide, (b) an aluminum oxide, (c) a zinc oxide, (d) a silicon carbide, (e) a boron nitride, (f) an aluminum nitride, or (g) a combination thereof. The first encapsulation layer may be selected from at least one of (a) a silicone, and (b) a polyolefin. The thermally conductive and electrically insulating layer may include at least one of (a) a layer of fluoropolymer, and (b) at least one of (i) an aluminum sheet, and (ii) a copper sheet. The thermally conductive and electrically insulating layer may be coupled to the thermal collector. The thermal collector may be selected from at least one of (a) at least one tube, and (b) at least one reservoir. The transparent layer may be selected from at least one of (a) a layer of glass, (b) an inert gas, (c) air, and (d) an additional layer of glass.

In one aspect, the integrated photovoltaic and thermal (PVT) module includes a layer of solar cells, a transparent layer, a first encapsulation layer, a second encapsulation layer, a thermally conductive and electrically insulating layer, and a thermal collector. The layer of solar cells includes an upper face that is exposed to solar radiation, and a lower face. The transparent layer is placed above the layer of solar cells. The transparent layer reduces a heat loss from the upper face of the layer of solar cells. The first encapsulation layer is encapsulated in between the transparent layer and the layer of solar cells. The first encapsulation layer conducts light energy from the solar radiation and transmits the light energy to the layer of solar cells. The first encapsulation layer is selected from at least one of (a) a silicone, and (b) a polyolefin. The second encapsulation layer is encapsulated below the layer of solar cells. The second encapsulation layer conducts heat energy from the layer of solar cells. The second encapsulation layer is selected from at least one of (a) a silicone, (b) a polyolefin, (c) a thermally conductive silicone, and (d) a thermally conductive polyolefin. The thermally conductive and electrically insulating layer is adapted to provide electrical insulation and thermal heat transfer. The thermally conductive and electrically insulating layer may include at least one of (a) a layer of fluoropolymer, and (b) at least one of (i) an aluminum sheet, and (ii) a copper sheet. The thermal collector, in contact with the thermally conductive and electrically insulating layer, is adapted to contain a heat transfer fluid. The thermally conductive and electrically insulating layer is placed in between the second encapsulation layer and the thermal collector. The thermally conductive and electrically insulating layer is coupled to the thermal collector. The thermal collector is selected from at least one of (a) at least one tube, and (b) at least one reservoir.

The integrated photovoltaic and thermal (PVT) module may further include (a) thermally insulated layer that is placed below the thermal collector, and (b) a back casing that is placed below the thermally insulated layer. The thermally insulated layer prevents a loss of heat energy from the thermally conductive and electrically insulating layer. The back casing provides support to the integrated PVT module. The second encapsulation may further include at least one thermally conductive filler to increase thermal conductivity of the second encapsulation layer. The at least one thermally conductive filler may be selected from at least one of (a) a ceramic nano sized particle, and (b) a ceramic micron sized particle. The at least one thermally conductive filler may be selected from a group that includes (a) a magnesium oxide, (b) an aluminum oxide, (c) a zinc oxide, (d) a silicon carbide, (e) a boron nitride, (f) an aluminum nitride, or (g) a combination thereof. The thermal collector may include at least one of (a) an aluminum material, and (b) a copper material. The layer of fluoropolymer may include a tedlar. The transparent layer may be selected from at least one of (a) a layer of glass, (b) an inert gas, (c) air, and (d) an additional layer of glass.

In another aspect, a method for manufacturing an integrated photovoltaic and thermal (PVT) module is provided. The method includes the following steps: (a) providing an encapsulation layer directly in contact with a lower face of a layer of solar cells, (b) adding at least one thermally conductive filler to the encapsulation layer to increase thermal conductivity of the encapsulation layer, (c) providing a thermal collector that is adapted to contain a heat transfer fluid, and (d) providing a thermally conductive and electrically insulating layer that is placed in between the encapsulation layer and the thermal collector to provide electrical insulation and thermal heat transfer. The encapsulation layer may be selected from at least one of (a) a silicone, (b) a polyolefin, (c) a thermally conductive silicone, and (d) a thermally conductive polyolefin. The thermally conductive and electrically insulating layer may include at least one of (a) a layer of fluoropolymer, and (b) at least one of (i) an aluminum sheet, and (ii) a copper sheet. The thermally conductive and electrically insulating layer may be coupled to the thermal collector. The thermal collector may be selected from at least one of (a) at least one tube, and (b) at least one reservoir. The at least one thermally conductive filler may be selected from at least one of (a) a ceramic nano sized particle, and (b) a ceramic micron sized particle. The at least one thermally conductive filler may be selected from a group that includes (a) a magnesium oxide, (b) an aluminum oxide, (c) a zinc oxide, (d) a silicon carbide, (e) a boron nitride, (f) an aluminum nitride, or (g) a combination thereof.

These and other aspects of the embodiments herein will be better appreciated and understood when considered in conjunction with the following description and the accompanying drawings. It should be understood, however, that the following descriptions, while indicating preferred embodiments and numerous specific details thereof, are given by way of illustration and not of limitation. Many changes and modifications may be made within the scope of the embodiments herein without departing from the spirit thereof, and the embodiments herein include all such modifications.

### BRIEF DESCRIPTION OF THE DRAWINGS

The embodiments herein will be better understood from the following detailed description with reference to the drawings, in which:

FIG. 1A illustrates a sectional view of an integrated photovoltaic and thermal (PVT) module according to an embodiment herein;

FIGS. 1B illustrates a sectional view of the integrated photovoltaic and thermal (PVT) module of FIG. 1A with glazing according to an embodiment herein;

FIG. 1C illustrates a sectional view of the integrated photovoltaic and thermal (PVT) module of FIG. 1B with a layer of polymer according to an embodiment herein;

FIGS. 2A through 2C illustrate top views of a thermal collector of the integrated photovoltaic and thermal module of FIG. 1A according to an embodiment herein; and

FIG. 3 is a flow diagram illustrating a method of manufacturing of the integrated photovoltaic and thermal (PVT) module of FIG. 1A according to an embodiment herein.

### DETAILED DESCRIPTION OF PREFERRED EMBODIMENTS

The embodiments herein and the various features and advantageous details thereof are explained more fully with reference to the non-limiting embodiments that are illustrated in the accompanying drawings and detailed in the following description. Descriptions of well-known components and processing techniques are omitted so as to not unnecessarily obscure the embodiments herein. The examples used herein are intended merely to facilitate an understanding of ways in which the embodiments herein may be practiced and to further enable those of skill in the art to practice the embodiments herein. Accordingly, the examples should not be construed as limiting the scope of the embodiments herein.

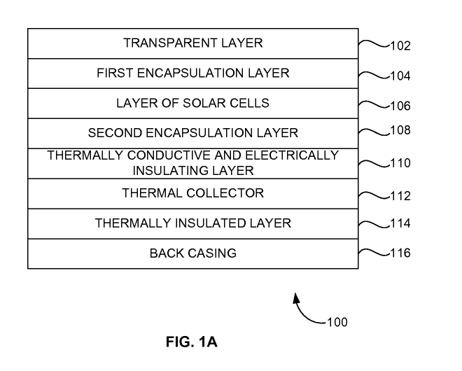

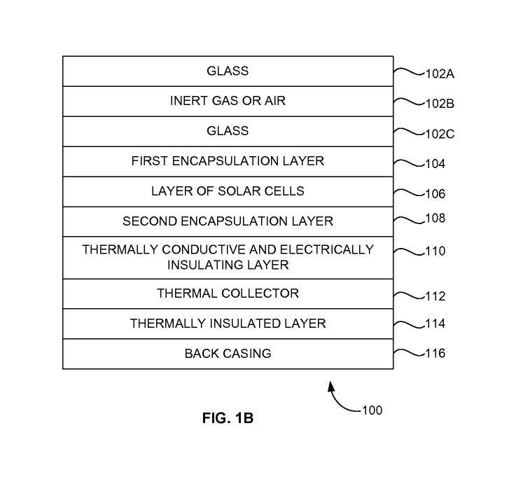

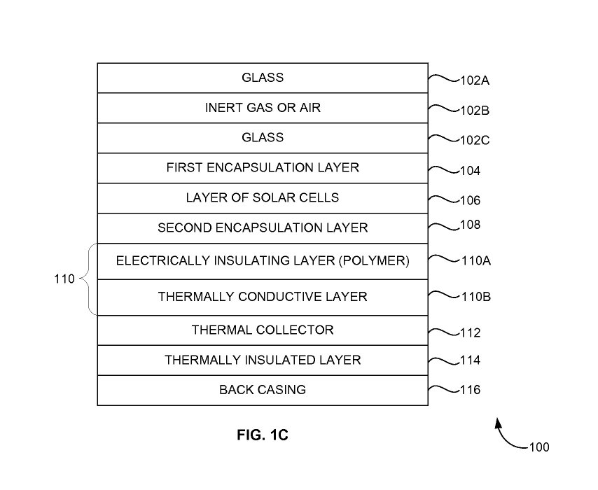

As mentioned, there remains a need for a PVT module that has higher temperature stability with increased thermal conductivity transfer between a photovoltaic (PV) layer (e.g., a layer of solar cells), and a heat-transfer medium (e.g., fluid, air, etc.). The embodiments herein achieve this by providing an integrated photovoltaic and thermal (PVT) module with a layer of solar cells that is laminated with an adjacent silicone, or a polyolefin based encapsulation layer, and a thermally conductive and electrically insulating layer to conduct excess heat from the layer of solar cells (i.e. a PV panel) into a thermal collector. The thermally conductive and electrically insulating layer includes a layer of fluoropolymer, and/or an aluminum/copper sheet. The layer of fluoropolymer enhances electrical insulation between the layer of solar cells, and a thermal collector. Referring now to the drawings, and more particularly to FIG. 1 through FIG. 3, where similar reference characters denote corresponding features consistently throughout the figures, there are shown preferred embodiments.

FIG. 1A illustrates a sectional view of an integrated photovoltaic and thermal (PVT) module 100 according to an embodiment herein. The integrated photovoltaic and thermal (PVT) module 100 includes a transparent layer 102, a first encapsulation layer 104, a layer of solar cells 106, a second encapsulation layer 108, a thermally conductive and electrically insulating layer 110, a thermal collector 112, a thermally insulated layer 114, and a back casing 116. The layer of solar cells 106 includes an upper face, and a lower face. The upper face of the layer of solar cells 106 is exposed to solar radiation. The layer of solar cells 106 converts light energy into electrical energy. The transparent layer 102 is placed above the layer of solar cells 106. The transparent layer 102 reduces a heat loss from the upper face of the layer of solar cells 106. In one embodiment, the transparent layer 102 includes a glass, an inert gas, an air, and/or an additional layer of glass. The first encapsulation layer 104 is encapsulated in between the transparent layer 102 and the layer of solar cells 106. The first encapsulation layer 104 conducts the light energy from the solar radiation and transmits the light energy to the layer of solar cells 106. In one embodiment, the first encapsulation layer 104 is a silicone, and/or a polyolefin. The second encapsulation layer 108 is encapsulated below the layer of solar cells 106 (i.e. the lower face of the layer of solar cells 106). The second encapsulation layer 108 conducts heat energy from the layer of solar cells 106. In one embodiment, the second encapsulation layer 108 is a silicone, a polyolefin, a thermal conductive silicone, and/or a thermal conductive polyolefin. The thermally conductive and electrically insulating layer 110, in thermal contact with the second encapsulation layer 108, is adapted to provide electrical insulation and thermal heat transfer.

The thermally conductive and electrically insulating layer 110 is coupled (e.g., welded, adhered or fastened) to the thermal collector 112. The thermal collector 112, in contact with the thermally conductive and electrically insulating layer 110, is adapted to contain a heat transfer fluid. In one embodiment, the thermal collector 112 is an aluminum or copper tube/reservoir. The thermally insulated layer 114 is placed below the thermal collector 112 to prevent a loss of heat energy from the thermally conductive and electrically insulating layer 110. The back casing 116 that is placed below the thermally insulated layer 114 provides a mechanical support to the integrated PVT module 100.

The integrated PVT module 100 may further include one or more thermally conductive fillers that are added to the second encapsulation layer 108 (e.g., a silicone, a polyolefin, a thermally conductive silicone, or a thermally conductive polyolefin). The addition of the one or more thermally conductive fillers makes the second encapsulation layer 108 more thermally conductive. In one embodiment, the one or more thermally conductive fillers are a ceramic nano sized particle, and/or a ceramic micron sized particle. In another embodiment, the one or more thermally conductive fillers are a magnesium oxide, an aluminum oxide, a zinc oxide, a silicon carbide, a boron nitride, an aluminum nitride, or a combination thereof.

With reference to FIG. 1A, FIG. 1B illustrates a sectional view of the integrated photovoltaic and thermal (PVT) module 100 of FIG. 1A with glazing according to an embodiment herein. The light from the solar radiation is incident on the PVT module 100 and passes through the transparent layer 102. The transparent layer 102 includes a layer of glass 102A, an inert gas/air 102B, and/or an additional layer of glass 102C. The light from the transparent layer 102 passes through the silicone, or polyolefin encapsulation material (i.e. the first encapsulation layer 104) and finally strikes the layer of solar cells 106 to generate electrical energy. The remaining excess heat from the layer of solar cells 106 is transferred to the aluminum or copper sheet (i.e. the thermally conductive and electrical insulating layer 110) through the second encapsulation layer 108 (e.g., a silicone, a polyolefin, a thermally conductive silicone, or a thermally conductive polyolefin). The thermal collector 112 (e.g., the aluminum or copper tube/reservoir) carrying fluid is coupled (e.g., welded, adhered, or fastened) to the aluminum/copper sheet 110. The thermally insulated layer 114 is added at the bottom of the integrated PVT module 100 to prevent a heat loss to the surroundings. The back casing 116 acts as a mechanical support for the integrated photovoltaic and thermal module 100.

With reference to FIGS. 1A and 1B, FIG. 1C illustrates a sectional view of the integrated photovoltaic and thermal (PVT) module 100 with a layer of polymer according to an embodiment herein. The thermally conductive and electrically insulating layer 110 includes an electrical insulating layer 110A (e.g., a layer of polymer), and a thermal conductive layer 110B (e.g., an aluminum/copper sheet). The layer of polymer 110A is placed in between the second encapsulation layer 108 and the aluminum/copper sheet 110B to increase the electrical resistivity. In one embodiment, the layer of polymer is a polypropylene, a polyamide, and/or a fluoropolymer. In another embodiment, the fluoropolymer is a tedlar, a polyvinyl fluoride, a polyvinylidene fluoride, a polytetrafluoroethylene. The thermally conductive and electrically insulating layer 110 enhances personal safety by providing electrical insulation between the layer of solar cells 106 and the thermal collector 112 using the layer of polymer 110A (e.g., a Teflon, a Polyvinyl fluoride, a Polyvinylidene fluoride, or other polymers like a Polypropylene, a Polyamide, etc.). The thermally conductive and electrically insulating layer 110 enhances thermal conductivity to the thermal collector 112 from the layer of solar cells 106. The aluminum/copper sheet 110B is placed below the electrically insulating layer 110A. The electrically insulating layer 110A and the thermally conductive layer 110B may combine as a single layer (i.e. a composite of the layer of polymer 110A, and the aluminum/copper sheet 110B), in one example embodiment. The aluminum/copper sheet 110B enhances thermal conductivity and prevents moisture penetration into the layer of solar cells 106 from a rear side of the integrated photovoltaic and thermal module 100, thereby protecting the layer of solar cells 106 from degradation. The layer of polymer 110A enhances thermal resistance between the layer of solar cells 106 and thermal collector 112, thereby reducing the thermal efficiency of the integrated photovoltaic and thermal (PVT) module 100.

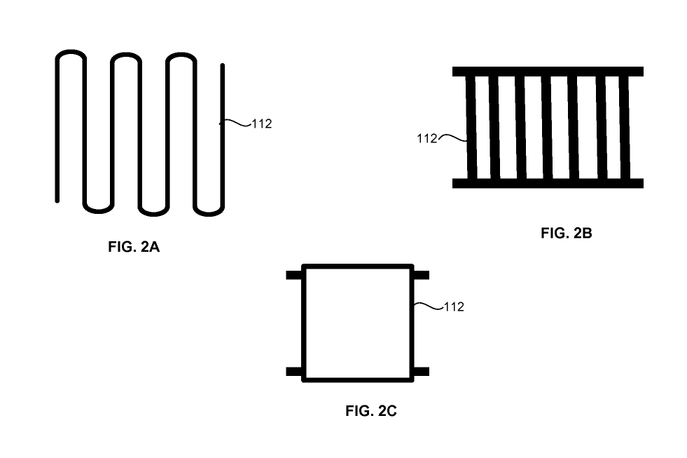

With reference to FIGS. 1A through 1C, FIGS. 2A through 2C illustrate top views of the thermal collector 112 of the integrated photovoltaic and thermal (PVT) module 100 of FIG. 1A according to an embodiment herein. The thermal collector 112 may include one or more aluminum/copper tube. The one or more aluminum/copper tube 112 may be configured in serpentine configuration, as shown in FIG. 2A, in one example embodiment. The one or more aluminum/copper tube 112 may be configured in grid like configuration, as shown in FIG. 2B, in another example embodiment. The one or more aluminum/copper tube 112 is adapted to contain heat transfer liquid to conduct heat from the aluminum/copper sheet 110B (e.g., the thermal conductive and electrically insulating layer 110). In one embodiment, the thermal collector 112 includes one or more aluminum/copper reservoir. The one or more aluminum/copper reservoir 112 may include one or more inlets, and/or one or more outlets, as shown in FIG. 2C.

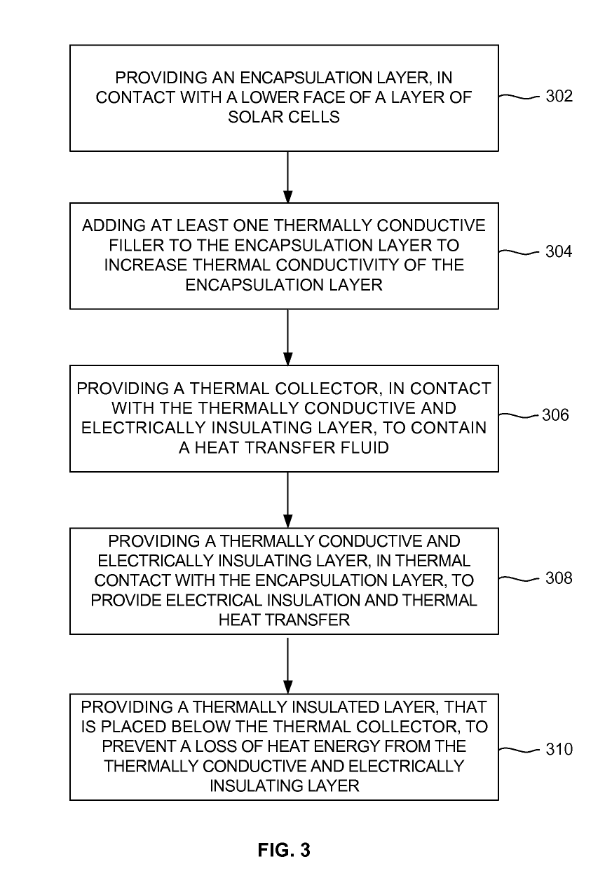

FIG. 3 is a flow diagram illustrating a method of manufacturing of the integrated photovoltaic and thermal (PVT) module 100 of FIG. 1A according to an embodiment herein. At step 302, an encapsulation layer (e.g., the second encapsulation layer 108) is encapsulated below a lower face of a layer of solar cells 106 to increase the thermal conductivity of the PVT module 100. In one embodiment, the encapsulation layer 108 is a silicone, a polyolefin, a thermally conductive silicone, and/or a thermally conductive polyolefin. At step 304, one or more thermally conductive fillers are added to the encapsulation layer 108 to increase thermal conductivity of the encapsulation layer 108. In one embodiment, the one or more thermally conductive fillers are a ceramic nano sized particle, and/or a ceramic micron sized particle. In another embodiment, the one or more thermally conductive fillers are a magnesium oxide, an aluminum oxide, a zinc oxide, a silicon carbide, a boron nitride, an aluminum nitride, or a combination thereof. At step 306, a thermal collector 112, in contact with the thermally conductive and electrically insulating layer 110, contains a heat transfer fluid. In one embodiment, the thermal collector 112 includes one or more tubes/reservoirs. At step 308, a thermally conductive and electrically insulating layer 110 is placed in between the encapsulation layer 108 and the thermal collector 112 to provide electrical insulation and thermal heat transfer. The thermally conductive and electrically insulating layer 110 may further include a layer of fluoropolymer, and/or an aluminum/copper sheet. The thermally conductive and electrically insulating layer 110 may be coupled (e.g., welded, adhered, or fastened) to the thermal collector 112. At step 310, a thermally insulated layer 114 is placed below the thermal collector 112 to prevent a loss of heat energy from the thermally conductive and electrically insulating layer 110.

Various other ceramic nano or micron sized fillers similar to a magnesium oxide, an aluminum oxide, a zinc oxide, a silicon carbide, a boron nitride, an aluminum nitride, or a combination thereof may be used for improving the thermal conductivity of a polyolefin, and/or a silicone. Alternatively, a thermally conductive EVA, and a thermally conductive PVB encapsulation material may be used for low temperature heating applications. Other encapsulation materials which can withstand above 100° Celsius may also be used for heating application.

The integrated photovoltaic and thermal module 100, in addition to generating electricity, may produce hot air, hot water, and/or hot fluid for the purpose of space heating, water heating, pre-heating, and/or solar cooling applications.

The integrated PVT module 100 is designed with a silicone, or a polyolefin as encapsulation material which can withstand in excess of 100° Celsius. The thermally conductive polyolefin or silicone is used as the back encapsulation (i.e. the second encapsulation layer 108) to enhance the thermal conductivity, and a heat flow from a layer of solar cells 106 to the thermal collector 112 without affecting the electrical conductivity.

The PVT module 100 is constructed with an additional encapsulation layer laminated with a silicone, a polyolefin, a thermally conductive silicone, and/or thermally conductive polyolefin based encapsulation layer (i.e. the second encapsulation layer 108) to conduct some of the excess heat into a thermal collector. The excess heat when sunlight is absorbed in the PVT module 100 is used to heat some circulating heat-transfer fluid below the layer of solar cells 106. The silicone and polyolefin encapsulation materials withstand more than 100° Celsius without degradation, thus making the silicone and polyolefin encapsulation materials suitable for the construction of integrated PVT modules 100. The thermal collector 112 acts as a back sheet, and provides support to the PVT module 100. The collected heat energy from the thermal collector 112 is used for space heating, water heating, and/or any similar applications. The thermal collector 112 of the PVT module 100 may be used as a conventional solar water heater.

The foregoing description of the specific embodiments will so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein can be practiced with modification within the spirit and scope of the appended claims.

What is claimed is:

1. An integrated photovoltaic and thermal (PVT) module comprising:
a layer of solar cells that comprises an upper face and a lower face, wherein said upper face is exposed to solar radiation;
a transparent layer that is placed above said layer of solar cells, wherein said transparent layer reduces a heat loss from said upper face of said layer of solar cells;
a first encapsulation layer that is encapsulated in between said transparent layer and said layer of solar cells, wherein said first encapsulation layer conducts light energy from said solar radiation and transmits said light energy to said layer of solar cells;
a second encapsulation layer that is encapsulated below said layer of solar cells, wherein said second encapsulation layer conducts heat energy from said layer of solar cells, wherein said second encapsulation layer is selected from at least one of (a) a silicone, (b) a polyolefin, (c) a thermally conductive silicone, and (d) a thermally conductive polyolefin;
a thermally conductive and electrically insulating layer that is adapted to provide electrical insulation and thermal heat transfer; and
a thermal collector, in contact with said thermally conductive and electrically insulating layer, that is adapted to contain a heat transfer fluid, wherein said thermally conductive and electrically insulating layer is placed in between said second encapsulation layer and said thermal collector.

2. The integrated PVT module of claim 1, further comprising:
a thermally insulated layer that is placed below said thermal collector, wherein said thermally insulated layer prevents a loss of heat energy from said thermally conductive and electrically insulating layer; and
a back casing that is placed below said thermally insulated layer, wherein said back casing provides support to said integrated PVT module.

3. The integrated PVT module of claim 1, wherein said second encapsulation comprises at least one thermally conductive filler to increase thermal conductivity of said second encapsulation layer.

4. The integrated PVT module of claim 3, wherein said at least one thermally conductive filler is selected from at least one of (a) a ceramic nano sized particle, and (b) a ceramic micron sized particle.

5. The integrated PVT module of claim 3, wherein said at least one thermally conductive filler is selected from a group comprising:
(a) a magnesium oxide,
(b) an aluminum oxide,
(c) a zinc oxide,
(d) a silicon carbide,
(e) a boron nitride,
(f) an aluminum nitride, or
(g) a combination thereof.

6. The integrated PVT module of claim 1, wherein said first encapsulation layer is selected from at least one of (a) a silicone, and (b) a polyolefin.

7. The integrated PVT module of claim 1, wherein said thermally conductive and electrically insulating layer comprises at least one of (a) a layer of fluoropolymer, and (b) at least one of (i) an aluminum sheet, and (ii) a copper sheet.

8. The integrated PVT module of claim 7, wherein said thermally conductive and electrically insulating layer is coupled to said thermal collector, wherein said thermal collector is selected from at least one of (a) at least one tube, and (b) at least one reservoir.

9. The integrated PVT module of claim 1, wherein said transparent layer is selected from at least one of (a) a layer of glass, (b) an inert gas, (c) air, and (d) an additional layer of glass.

10. An integrated photovoltaic and thermal (PVT) module comprising:
a layer of solar cells that comprises an upper face and a lower face, wherein said upper face is exposed to solar radiation;
a transparent layer that is placed above said layer of solar cells, wherein said transparent layer reduces a heat loss from said upper face of said layer of solar cells;
a first encapsulation layer that is encapsulated in between said transparent layer and said layer of solar cells, wherein said first encapsulation layer conducts light energy from said solar radiation and transmits said light energy to said layer of solar cells, wherein said first encapsulation layer is selected from at least one of (a) a silicone, and (b) a polyolefin;
a second encapsulation layer that is encapsulated below said layer of solar cells, wherein said second encapsulation layer conducts heat energy from said layer of solar cells, wherein said second encapsulation layer is selected from at least one of (a) a silicone, (b) a polyolefin, (c) a thermally conductive silicone, and (d) a thermally conductive polyolefin;
a thermally conductive and electrically insulating layer that is adapted to provide electrical insulation and thermal heat transfer, wherein said thermally conductive and electrically insulating layer comprises at least one of (a) a layer of fluoropolymer, and (b) at least one of (i) an aluminum sheet, and (ii) a copper sheet; and
a thermal collector, in contact with said thermally conductive and electrically insulating layer, that is adapted to contain a heat transfer fluid,
wherein said thermally conductive and electrically insulating layer is placed in between said second encapsulation layer and said thermal collector, wherein said thermally conductive and electrically insulating layer is coupled to said thermal collector, wherein said thermal collector is selected from at least one of (a) at least one tube, and (b) at least one reservoir.

11. The integrated PVT module of claim 10, further comprising:
a thermally insulated layer that is placed below said thermal collector, wherein said thermally insulated layer prevents a loss of heat energy from said thermally conductive and electrically insulating layer; and
a back casing that is placed below said thermally insulated layer, wherein said back casing provides support to said integrated PVT module.

12. The integrated PVT module of claim 10, wherein said second encapsulation layer comprises at least one thermally conductive filler to increase thermal conductivity of said second encapsulation layer.

13. The integrated PVT module of claim 12, wherein said at least one thermally conductive filler is selected from at least one of (a) a ceramic nano sized particle, and (b) a ceramic micron sized particle.

14. The integrated PVT module of claim 12, wherein said at least one thermally conductive filler is selected from a group comprising:
(a) a magnesium oxide,
(b) an aluminum oxide,
(c) a zinc oxide,
(d) a silicon carbide,
(e) a boron nitride,
(f) an aluminum nitride, or
(g) a combination thereof.

15. The integrated PVT module of claim 10, wherein said thermal collector comprises at least one of (a) an aluminum material, and (b) a copper material.

16. The integrated PVT module of claim 11, wherein said layer of fluoropolymer comprises a tedlar.

17. A method for manufacturing an integrated photovoltaic and thermal (PVT) module comprising:
providing an encapsulation layer directly in contact with a lower face of a layer of solar cells, wherein said encapsulation layer is selected from at least one of (a) a silicone, (b) a polyolefin, (c) a thermally conductive silicone, and (d) a thermally conductive polyolefin;
adding at least one thermally conductive filler to said encapsulation layer to increase thermal conductivity of said encapsulation layer;
providing a thermal collector that is adapted to contain a heat transfer fluid; and
providing a thermally conductive and electrically insulating layer that is placed in between said encapsulation layer and said thermal collector to provide electrical insulation and thermal heat transfer, wherein said thermally conductive and electrically insulating layer comprises at least one of (a) a layer of fluoropolymer, and (b) at least one of (i) an aluminum sheet, and (ii) a copper sheet.

18. The method of claim 17, wherein said thermally conductive and electrically insulating layer is coupled to said thermal collector, wherein said thermal collector is selected from at least one of (a) at least one tube, and (b) at least one reservoir.

19. The method of claim 17, wherein said at least one thermally conductive filler is selected from at least one of (a) a ceramic nano sized particle, and (b) a ceramic micron sized particle.

20. The method of claim 17, wherein said at least one thermally conductive filler is selected from a group comprising:
(a) a magnesium oxide,
(b) an aluminum oxide,
(c) a zinc oxide,
(d) a silicon carbide,
(e) a boron nitride,
(f) an aluminum nitride, or
(g) a combination thereof.
